(19) United States
(12) Patent Application Publication
(10) Pub. No.: US 2009/0051174 A1
(43) Pub. Date: Feb. 26, 2009

(54) Engaging apparatus and electronic equipment utilizing the same

(75) Inventor: Yung-Shun Ho, Tao Yuan Shien (TW)

Correspondence Address: REED SMITH LLP, 3110 Fairview Park Drive, Suite 1400, Falls Church, VA, 22042, US

(73) Assignee: Quanta Computer Inc.

(21) Appl. No.: 12/010,601

(22) Filed: Jan. 28, 2008

(30) Foreign Application Priority Data
Aug. 24, 2007 (TW) 096131333

(51) Int. Cl. E05C 17/56; H05K 7/14

(52) U.S. Cl. 292/251.5; 361/681; 361/685

(57) ABSTRACT

The invention discloses an engaging apparatus applied to equipment. The engaging apparatus includes an engaging device and a second magnetic member. The engaging device is movably disposed in a cover of the equipment, and includes a first magnetic member and an engaging member. The second magnetic member is also disposed in the cover and corresponds to the first magnetic member. The cover thereon defines a first position and a second position. When the engaging device is operated to move from the first position to the second position, a magnetic force generated between the second magnetic member and the first magnetic member assists in turning back the engaging device to the first position.

### BACKGROUND OF THE INVENTION

1. Field of the Invention

The invention relates to an engaging apparatus applied to electronic equipment and, more particularly, to an engaging apparatus which utilizes magnetic forces to assist in turning back an engaging device to the original position.

2. Description of the Prior Art

Recently, many kinds of electronic equipments, such as laptop, have been getting more and more popular and favoring by many customers because they are light and portable; moreover, many novel models and functions are launched continuously on the market.

In the present, a spring locking apparatus is mostly adopted as a switch of a cover of commonly electronic equipment on the market. That is to say, when the cover of the laptop is closed by a user, the spring locking apparatus utilizes an elastic force generated by a spring to assist in engaging an engaging member (ex. tenon) located at the cover with a restraint member (ex. groove) located at a base to form a locking engagement. When the user wants to open the cover, he/she only has to operate the apparatus to move toward the opposite direction to release the locking engagement.

However, when the spring locking apparatus is used unceasingly, the elastic force of the spring will get fatigued gradually and broken down finally. Furthermore, the cover of the equipment will become unable to be locked and easy to be collided and damaged.

Accordingly, the scope of the invention is to provide an engaging apparatus applied to electronic equipment, so as to solve the aforesaid problems.

### SUMMARY OF THE INVENTION

The invention provides an engaging apparatus applied to electronic equipment. The engaging apparatus utilizes magnetic forces generated among magnets to substitute for elastic forces generated by springs to assist in turning back an engaging device to the original position.

According to an embodiment of the invention, the invention provides an engaging apparatus applied to an equipment. The engaging apparatus comprises an engaging device and a second magnetic member. The engaging device is movably disposed in a cover of the equipment and comprises a first magnetic member and an engaging member. The second magnetic member is also disposed in the cover and corresponds to the first magnetic member. The cover thereon defines a first position and a second position. When the engaging device is operated to move from the first position to the second position, a magnetic force generated between the first magnetic member and the second magnetic member assists in turning back the engaging device to the first position. Besides, with the placement of the engaging apparatus, the magnetic members can cooperate with a reed switch of the electronic equipment to control a power switch on/off.

The advantage and spirit of the invention may be understood by the following recitations together with the appended drawings.

### BRIEF DESCRIPTION OF THE APPENDED DRAWINGS

FIG. 1A is a schematic diagram illustrating an engaging apparatus as an engaging device is located at a first position according to a first embodiment of the invention.

FIG. 1B is a schematic diagram illustrating an engaging apparatus as an engaging device is located at a second position according to a first embodiment of the invention.

FIG. 2 is a perspective view illustrating an electronic equipment according to a second embodiment of the invention.

### DETAILED DESCRIPTION OF THE INVENTION

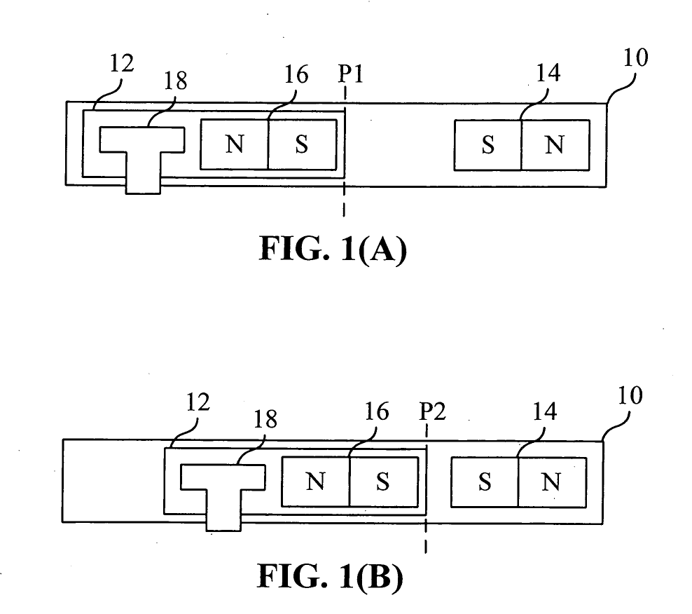

According to a first embodiment of the invention, the invention refers to an engaging apparatus which can be applied to any equipment required of locking a cover to a base, such as laptops, folding mobile phones and electronic entertainment devices. Please refer to FIG. 1. FIG. 1 is a schematic diagram illustrating an engaging apparatus. As shown in FIG. 1, the engaging apparatus 10 is located at a cover of an equipment and comprises an engaging device 12 and a second magnetic member 14. The engaging device 12 can be movably disposed in the cover and comprises a first magnetic member 16 and an engaging member 18. Also, the second magnetic member 14 is disposed in the cover and corresponds to the first magnetic member 16. As shown in FIG. 1(A) and FIG. 1(B), the cover thereon defines a first position P1 and a second position P2. When the engaging device 12 is operated to move from the first position P1 to the second position P2, a magnetic force (repulsive force) generated between the first magnetic member 16, and the second magnetic member 14 assists in turning back the engaging device 12 to the first position P1.

In the practical application, the engaging apparatus 10 can further comprise a restraint member (not shown in FIG. 1). The restraint member is usually disposed in a base of the equipment. When the engaging device 12 is located at the first position P1, the engaging member 18 can be cooperated with the restraint member to form a locking engagement. On the other hand, when the engaging device 12 is located at the second position P2, the locking engagement will be released.

For instance, the restraint member and the engaging member 18 of the engaging apparatus 10 can respectively be a groove and a tenon, and the tenon can be cooperated with the groove. After the cover of the equipment is closed with respect to the base, the tenon is located at the first position P1, and the tenon can be cooperated with the groove to form a locking engagement. The locking engagement represents that the cover is in the state of being locked to the base. On the other hand, when the tenon is located at the second position P2, the locking engagement formed by the tenon and the groove will be released. That is to say, when the tenon is located at the second position P2, the cover can be separated from the base.

Besides, the first magnetic member 16 and the second magnetic member 14 can respectively be a magnet, but not limited to this. According to the invention, terminal portions of two magnets in opposition to each other should be the same in polarity. For instance, assume that the first magnetic member 16 is a first magnet and the second magnetic member 14 is a second magnet. As shown in FIG, 1, if the first magnet utilizes S-terminal portion to face the second magnet, the second magnet has to utilize S-terminal portion to face the first magnet too. Similarly, if the first magnet utilizes N-terminal portion to face the second magnet, the second magnet has to utilize N-terminal portion to face the first magnet too. Accordingly, when the first magnet approaches the second magnet, a repulsively magnetic force will be generated between the first magnet and the second magnet. As mentioned above, when the engaging device 12 is operated to move from the first position P1 to the second position P2, the magnetic force generated between the first magnet and the second magnet assists in turning back the engaging device 12 to the first position P1.

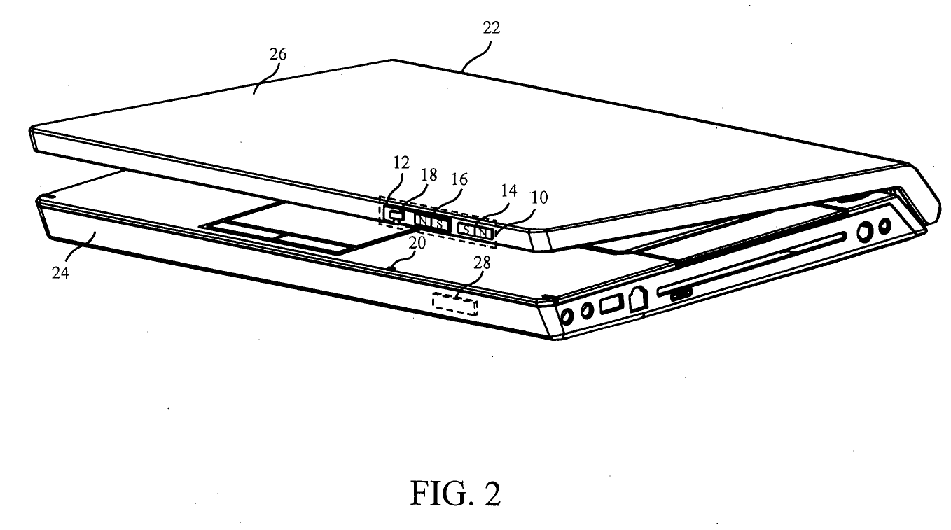

According to a second embodiment of the invention, the invention relates to an electronic equipment. And, the electronic equipment can be any apparatus which needs to lock a cover to a base, such as laptops, folding mobile phones and electronic entertainment devices. Please refer to FIG. 2. FIG. 2 is a perspective view illustrating an electronic equipment according to a second embodiment of the invention. As shown in FIG. 2, the electronic 22 comprises a base 24, a cover 26 and an engaging apparatus 10. The engaging apparatus 10 is movably disposed in the cover 26 and comprises an engaging device 12 and a second magnetic member 14. The engaging device 12 comprises a first magnetic member 16 and an engaging member 18. The second magnetic member 14 corresponds to the first magnetic member 16. The cover 26 is thereon defined a first position P1 and a second position P2. When the engaging device 12 is operated to move from the first position P1 to the second position P2, a magnetic force 14 generated between the second magnetic member 14 and the first magnetic member 16 assists in turning back the engaging device 12 to the first position P1.

In practical applications, the electronic equipment 22 can further comprise a restraint member 20. The restraint member 20 is disposed in a base 24 of the equipment. When the engaging device 12 is located at the first position P1, the engaging member 18 can be cooperated with the restraint member 20 to form a locking engagement. On the other hand, when the engaging device 12 is located at the second position P2, the locking engagement will be released.

In the embodiment shown in FIG. 2, the electronic equipment 22 is a laptop, and the restraint member 20 and the engaging member 18 can respectively be a groove and a tenon. The tenon can be cooperated with the groove. When the tenon is located at the first position PI and if the cover 26 of the laptop is closed with respect to the base 24, the tenon can be cooperated with the groove to form a locking engagement. The locking engagement represents that the cover 26 forms a locking condition with the base 24. On the other hand, when the tenon is located at the second position P2, the locking engagement formed by the tenon and the groove will be released.

Besides, the first magnetic member 16 and the second magnetic member 14 can respectively be a magnet, but not limited to this. According to the invention, the terminal portions of two magnets in opposition to each other should be the same in polarity. For instance, assume that the first magnetic member 16 is a first magnet and the second magnetic member 14 is a second magnet. As shown in FIG. 2, if the first magnet utilizes S-terminal portion to face the second magnet, the second magnet has to utilize S-terminal portion to face the first magnet, too. Similarly, if the first magnet utilizes N-terminal portion to face the second magnet, the second magnet has to utilize N-terminal portion to face the first magnet, too. Accordingly, when the first magnet approaches the second magnet, a repulsively magnetic force will be generated between the first magnet and the second magnet. As mentioned above, when the engaging device 12 is operated to move from the first position P1 to the second position P2, the repulsively magnetic force generated between the first magnet and the second magnet assists in turning back the engaging device 12 to the first position P1.

In practical applications, the electronic equipment 22 can further comprise a reed switch 28 or magnetic sensor, such as hall sensor, as shown in FIG. 2. An open loop/close loop condition of the reed switch 28 is related to a magnetic field intensity detected by the reed switch 28. When an angle between the cover 26 and the base 24 is larger than a threshold, the cover 26 is opened by a user; for example, since the reed switch 28 is far away from the first magnetic member 16 and the second magnetic member 14 gradually, the detected magnetic field intensity is relatively decreased gradually. Once the detected magnetic field intensity is smaller than a predetermined value, the reed switch 28 will transmit a signal to the electronic equipment 22, and the electronic equipment 22 will switch on a part of components in the electronic equipment 22, such as a screen or a hard disc, according to the signal.

Similarly, when an angle between the cover 26 and the base 24 is smaller than a threshold, the cover 26 is closed by a user; for example, since the reed switch 28 approaches the first magnetic member 16 and the second magnetic member 14 gradually, the detected magnetic field intensity is relatively increased gradually. Once the detected magnetic field intensity is larger than a predetermined value, the reed switch 28 will transmit a signal to the electronic equipment 22, and the electronic equipment 22 will switch off a part of components in the electronic equipment 22, such as a screen or a hard disc, according to the signal.

Compared with the prior art, the engaging apparatus and the electronic equipment applying the same according to the invention not only save them from utilizing the spring in prior art and avoid elastic fatigue, but also control a power switch on/off by cooperating with a reed switch, so as to save power consumption.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An engaging apparatus applied to an equipment, comprising:
an engaging device, movably disposed in a cover of the equipment, comprising a first magnetic member and an engaging member; and
a second magnetic member, disposed in the cover, corresponding to the first magnetic member;
wherein the cover thereon defines a first position and a second position; when the engaging device is operated to move from the first position to the second position, a magnetic force generated between the second magnetic member and the first magnetic member assists in turning back the engaging device to the first position.

2. The engaging apparatus of claim 1, further comprising:
a restraint member disposed in a base of the equipment;
wherein when the engaging device is located at the first position, the engaging member is cooperated with the restraint member to form a locking engagement.

3. The engaging apparatus of claim 2, wherein the locking engagement is released when the engaging device is located at the second position.

4. The engaging apparatus of claim 2, wherein the restraint member is a groove.

5. The engaging apparatus of claim 1, wherein the engaging member is a tenon.

6. The engaging apparatus of claim 1, wherein the first magnetic member and the second magnetic member are magnets.

7. An electronic equipment, comprising:
a base;
a cover pivotally connected to the base; and
an engaging apparatus movably disposed in the cover, comprising:
an engaging device comprising a first magnetic member and an engaging member; and
a second magnetic member corresponding to the first magnetic member;
wherein the cover thereon defines a first position and a second position; when the engaging device is operated to move from the first position to the second position, a magnetic force generated between the second magnetic member and the first magnetic member assists in turning back the engaging device to the first position.

8. The electronic equipment of claim 7, further comprising:
a restraint member disposed in the base;
wherein when the engaging device is located at the first position, the engaging member is cooperated with the restraint member to form a locking engagement.

9. The electronic equipment of claim 8, wherein the locking engagement is released when the engaging device is located at the second position.

10. The electronic equipment of claim 8, wherein the restraint member is a groove.

11. The electronic equipment of claim 7, wherein the engaging member is a tenon.

12. The electronic equipment of claim 7, wherein the first magnetic member and the second magnetic member are magnets.

13. The electronic equipment of claim 7, further comprising:
a reed switch for transmitting a first signal to the electronic equipment when an angle between the cover and the base is larger than a threshold, the electronic equipment switching on a component of the electronic equipment based on the first signal.

14. The electronic equipment of claim 13, wherein the component is a screen or a hard disc.

15. The electronic equipment of claim 13, wherein the reed switch comprises a hall sensor.

16. The electronic equipment of claim 7, further comprising:
a reed switch for transmitting a second signal to the electronic equipment when an angle between the cover and the base is smaller than a threshold, the electronic equipment switching off a component of the electronic equipment based on the second signal.

17. The electronic equipment of claim 16, wherein the component is a screen or a hard disc.

18. The electronic equipment of claim 13, further comprising:
a reed switch for transmitting a second signal to the electronic equipment when an angle between the cover and the base is smaller than a threshold, the electronic equipment switching off a component of the electronic equipment based on the second signal.

19. The electronic equipment of claim 18, wherein the reed switch comprises a hall sensor.

20. The electronic equipment of claim 18, wherein the component is a screen or a hard disc.
